(19) United States
(12) Patent Application Publication
(10) Pub. No.: US 2026/0126469 A1
(43) Pub. Date: May 7, 2026

(54) PROBE HEAD, PROBE CARD ASSEMBLY AND METHOD FOR MANUFACTURING PROBE HEAD

(71) Applicant: Taiwan Semiconductor Manufacturing Company, Ltd., Hsinchu (TW)

(72) Inventors: Kuan Chun Chen, Hsinchu City (TW); Guang-Sing Huang, Hsinchu County (TW); Shu An Shang, Kaohsiung City (TW); Hsiou-Yu He, Hsinchu (TW); Kai-Yi Tang, New Taipei City (TW); Tsai-Ning Lu, MiaoLi County (TW)

(73) Assignee: Taiwan Semiconductor Manufacturing Company, Ltd., Hsinchu (TW)

(21) Appl. No.: 18/935,687

(22) Filed: Nov. 4, 2024

(51) Int. Cl. G01R 1/073; G01R 3/00

(52) U.S. Cl. CPC G01R 1/07314; G01R 3/00

(57) ABSTRACT

A probe head for performing an electrical test on a device under test (DUT) includes an upper substrate including a plurality of upper through holes, a lower substrate assembly disposed under the upper substrate and including a plurality of lower through holes corresponding to the plurality of upper through holes respectively, a spacer connected between the upper substrate and the lower substrate assembly to maintain a gap between the upper substrate and the lower substrate assembly, a plurality of first probes extending through the plurality of upper through holes and the plurality of lower through holes respectively, an interconnect structure disposed on the lower substrate assembly and comprising a dielectric layer and a circuit layer, and a plurality of second probes disposed on the interconnect structure and electrically connected to one another through the circuit layer.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon. Many integrated circuits are typically manufactured on a single semiconductor wafer. The dies of the wafer may be processed and packaged at the wafer level, and various technologies have been developed for wafer level packaging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross sectional view of a probe head according to some embodiments of the present disclosure.

FIG. 2 to FIG. 8 illustrate cross sectional views of intermediate stages in the manufacturing of a probe card assembly according to some embodiments of the present disclosure.

FIG. 9 illustrates a partial bottom view of a lower substrate assembly of a probe head according to some embodiments of the present disclosure.

FIG. 10 illustrates a partial bottom view of a lower substrate assembly of a probe head according to other embodiments of the present disclosure.

FIG. 11 illustrates a cross sectional view of a probe card assembly during testing according to some embodiments of the present disclosure.

FIG. 12 to FIG. 17 illustrate cross sectional views of intermediate stages in the manufacturing of a probe card assembly according to some embodiments of the present disclosure.

FIG. 18 illustrates a cross sectional view of a probe card assembly according to some embodiments of the present disclosure.

FIG. 19 to FIG. 23 illustrate cross sectional views of intermediate stages in the manufacturing of a probe card assembly according to some embodiments of the present disclosure.

FIG. 24 illustrates a cross sectional view of a probe card assembly according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

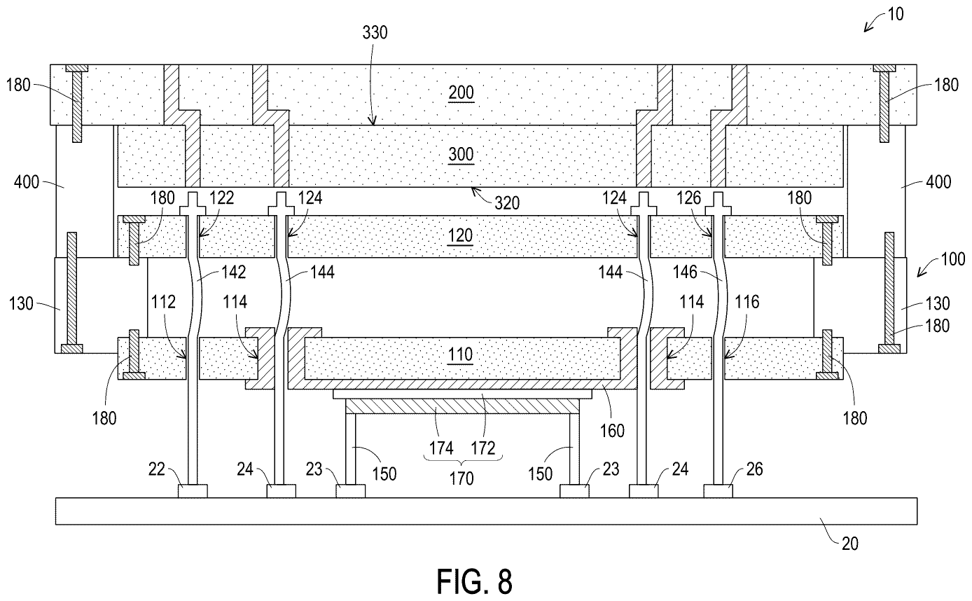

A probe head, probe card having the probe head and a method for manufacturing the probe head are provided for performing an electrical test on a device under test (DUT) (e.g., DUT 20 shown in FIG. 8). The device under test may be a semiconductor wafer in accordance with some embodiments of the disclosure. In general, semiconductor fabrication involves numerous steps including photolithography, material deposition, and etching to form a plurality of individual semiconductor devices or integrated circuit chips (dies) on a single semiconductor wafer. Some of the individual chips formed on the wafer, however, may have defects due to variances and problems that may arise during the intricate semiconductor fabrication process. Prior to wafer dicing wherein the individual integrated circuit chips (dies) are separated from the semiconductor wafer, electrical performance and reliability tests are performed on a plurality of chips simultaneously by, for example, energizing them for a predetermined period of time (i.e., wafer level burn-in testing). The resulting electrical signals generated from the device under test are captured and analyzed by an automatic test equipment (ATE) having test circuitry to determine if a chip has a defect.

The probe head includes a plurality of contact elements (also known as probes, pins, needles, etc.), which are divided into contact elements suitable to carry power and ground signals towards the device under test, and into contact elements apt to carry operating signals, in particular input/output signals, between the test equipment and the device under test. For testing of high speed serial data transmission devices or integrated circuits, a possible method of shorting two or more contact pads of the device under test is adopted, which is known in the field as “loop-back”. The implementation is to short two contact pads of the device under test by means of the probes of the probe card, wherein a first probe carries a signal from a first pad of the device under test towards the probe card and then the signal is closed on a second pad of the device under test by means of a second probe which contacts said second pad. In this case, however, long transmission paths of the signal from the device under test to the loopback circuits of the probe card and vice versa causes a reduction of the frequency performance of the probe card.

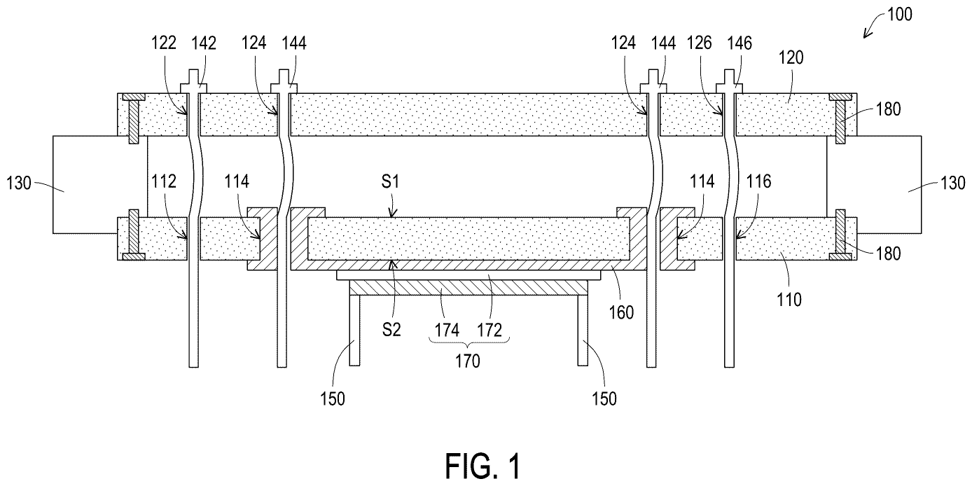

Accordingly, to improve frequency performance of testing equipment, a probe head 100 with shorter path of electrical signal from the device under test to the loopback circuit in the probe head 100 is provided. FIG. 1 illustrates a cross sectional view of a probe head according to some embodiments of the present disclosure. Referring to FIG. 1, in some embodiments, the probe head 100 includes a lower substrate assembly 110, an upper substrate 120, a spacer 130, a plurality of first probes 142, 144, 146, an interconnect structure 170, and a plurality of second probes 150. The upper substrate 120 includes a plurality of upper through holes 122, 124, 126 and the lower substrate assembly 110 includes a plurality of lower through holes 112, 114, 116 corresponding to the plurality of upper through holes 122, 124, 126 respectively. The lower substrate assembly 110 is disposed under the upper substrate 120, so that the first probes 142, 144, 146 can extend through the upper through holes 122, 124, 126 and the lower through holes 112, 114, 116 respectively.

The spacer 130 is connected between the upper substrate 120 and the lower substrate assembly 110 to maintain a gap between the upper substrate 120 and the lower substrate assembly 110. That is, the lower substrate assembly 110, the upper substrate 120, and the spacer 130 jointly form a cavity C1. In the present embodiment, the lower substrate assembly 110 and the upper substrate 120 are mounted on an upper portion and a lower portion of the spacer 130 through fixing elements, such as screws, respectively. The upper through holes 122, 124, 126 are precisely aligned with the lower through holes 112, 114, 116, so the first probes 142, 144, 146 can extend through the upper through holes 122, 124, 126 and the lower through holes 112, 114, 116 respectively.

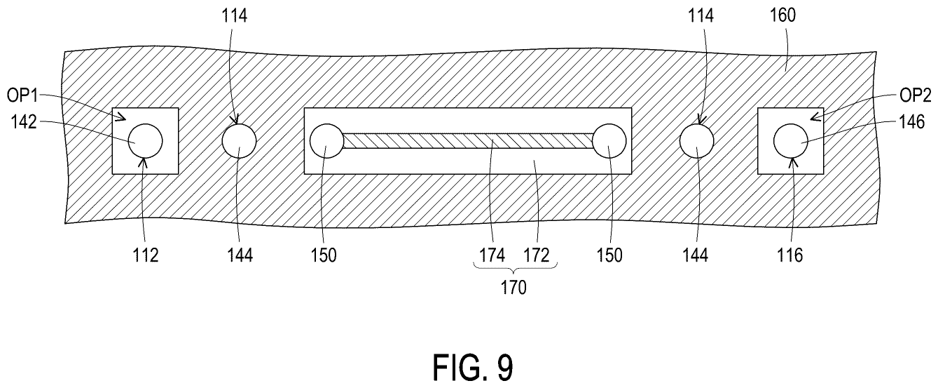

The upper substrate 120 is configured to receive upper of the first probes 142, 144, 146, and the spacer 130 is interposed between the lower substrate assembly 110 and the upper substrate 120. The upper contact ends of the first probes 142, 144, 146 extend through the upper substrate 120 to connect with contact pads on the probe card (e.g., the circuit board 200 of the probe card assembly shown in FIG. 9). The lower contact ends of the first probes 142, 144, 146 protrude out from the lower substrate assembly 110 to connect with contact pads on the device under test (e.g., the DUT 20 shown in FIG. 9).

In accordance with some embodiments of the disclosure, the interconnect structure 170 is disposed on the lower substrate assembly 110, and the second probes 150 are disposed on the interconnect structure 170. In some embodiments, the interconnect structure 170 includes a dielectric layer 172 and a circuit layer 174. The circuit layer 174 disposed over the dielectric layer 172 and the second probes 150 are electrically connected to one another through the circuit layer 174. By electrically connecting the second probes 150 through the interconnect structure 170 disposed on the lower substrate assembly 110, the electrical path of the signal from the device under test to the loopback circuit of the probe head 100 can be shorten, so as to increase the frequency performance of the probe head 100.

In some embodiments, the lower substrate assembly 110 includes a lower substrate 110 having the lower through holes 112, 114, 116, and the interconnect structure 170 is disposed on a lower surface of the lower substrate 110 that faces the DUT. With such arrangement, the lower substrate 110 and the upper substrate 120 can be made of ceramic materials, and the spacer 130 can be made of metal, such as aluminum or other suitable materials, but the disclosure is not limited in this respect. In the present embodiment, a dielectric constant of the dielectric layer 172 is lower than a dielectric constant of the lower substrate 110. For example, the dielectric layer 172 can be typically formed with dielectric materials having low dielectric constant (low-k) or extremely low dielectric constant in an effort to reduce parasitic capacitance of the circuit layer 174 formed thereon, thus increasing signal speed and enhance signal integrity. In one embodiment, the dielectric layer 172 may have a dielectric constant less than 8, and is formed with a porous organic dielectric material. As an example, the dielectric layer 172 includes diamond-like carbon (DLC), pure silica zeolite, phosphosilicate glass (PSG), borophosphosilicate glass (BPSG), fluorinated silicate glass (FSG), SiOxCy, Spin-On-Glass, Spin-On-Polymers, silicon carbon material, compounds thereof, composites thereof, combinations thereof, or the like, by any suitable method known in the art, such as spinning, chemical vapor deposition (CVD), and plasma-enhanced CVD (PECVD). It should also be noted that the dielectric layer 172 may include a plurality of dielectric layers.

In some embodiments, the lower substrate assembly 110 may further include an adhesive layer 160, and the dielectric layer 172 of the interconnect structure 170 is formed over the adhesive layer 160 on the lower substrate assembly 110. The adhesive layer 160 can be made with a single layer, or multiple layers using an adhesion layer of Cr, Ti, Al, Ni, W, Pt Au, any combination thereof, or the like, for example. In one embodiment, the adhesive layer 160 is conductive and includes a first layer with higher adhesion and lower electrical conductivity, such as Cr, Ti, Al, Ni, W, etc., and a second layer with lower adhesion and higher electrical conductivity, such as Pt Au, etc. The formation methods include electrolytic plating, electroless plating, sputtering, CVD methods, PVD methods, and the like.

In some embodiments, the first probes 142, 144, 146 includes at least one ground probe 144 for contacting a ground pad of the DUT (e.g., the ground pad 24 of the DUT 20 in FIG. 8). The ground probes 144 extend through the upper through holes 124 and the lower through holes 114 and protrude therefrom. To improve power coupling integrity and reduce coupling resistance of the circuit layer 174, the adhesive layer 160 may be grounding by coupled to the ground probes 144. In some embodiments, the adhesive layer 160 is conductive and covers a lower surface of the lower substrate assembly 110 and inner surfaces of the lower through holes 114 in a conformal manner. As such, the adhesive layer 160 can be in contact with the ground probes 144 and grounding when the ground probes 144 is in the lower through holes 114.

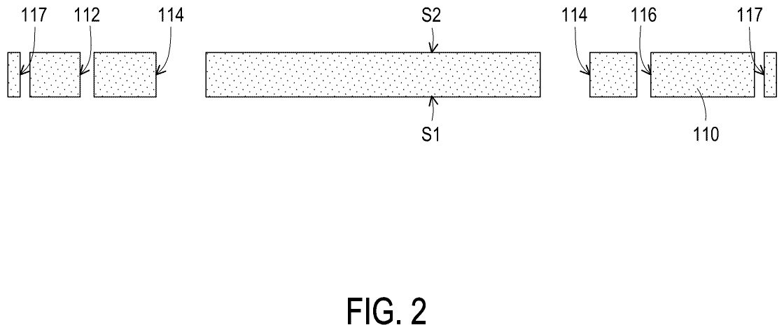

FIG. 2 to FIG. 8 illustrate cross sectional views of intermediate stages in the manufacturing of a probe card assembly according to some embodiments of the present disclosure. It is understood that additional operations can be provided before, during, and after the processes shown by FIG. 2 to FIG. 8, and some of the operations described below can be replaced or eliminated, for additional embodiments of the method. The order of the operations/processes may be interchangeable. Material, configuration, dimensions and/or processes the same as or similar to the foregoing embodiments described with FIG. 2 to FIG. 8 may be employed in the following embodiments, and detailed explanation thereof may be omitted.

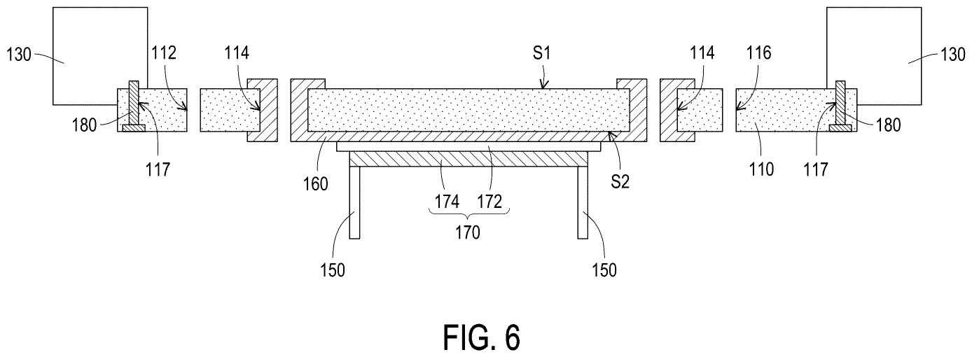

Referring firstly to FIG. 1 and FIG. 2, in some embodiments, a lower substrate 110 is provided. The lower substrate 110 includes a plurality of lower through holes 112, 114, 116 that the first probes 142, 144, 146 of FIG. 1 can pass through, and a plurality of assembling holes 117 that fixing elements 180 of FIG. 6 can screw in. For example, the first probes may include one I/O probe 142, two ground probes 144, and one power probe 146, and the lower substrate 110 includes one I/O through hole 112, two ground through hole 114, and one power through hole 116 for receiving the corresponding I/O probe 142, ground probes 144, and power probe 146 therein, but the claimed scope is not limited in this respect. The lower substrate 110 can be made of ceramic material or other suitable materials.

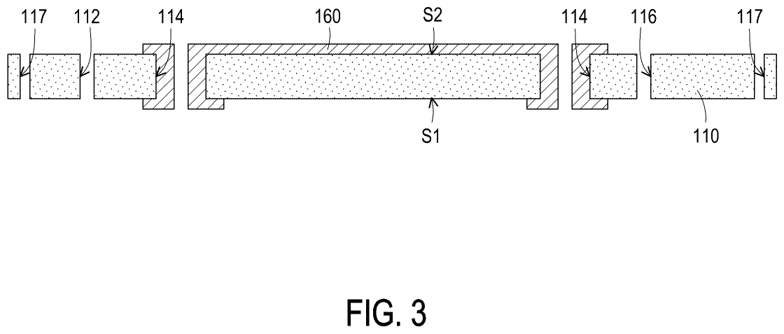

Referring to FIG. 1 and FIG. 3, the adhesive layer 160 is formed on a surface of the lower substrate 110. In the embodiment, the adhesive layer 160 is formed on a lower surface S2 of the lower substrate 110, which would face the DUT during electrical test. It is noted that the lower surface S2 of the lower substrate 110 faces up in FIG. 2 to FIG. 5 for performing manufacturing process over the lower surface S2, and would face down toward the DUT during operation of electrical test. The spatially relative terms such as “lower” and “upper” are intended to encompass different orientations of the device in use or operation in addition to the orientation depicted in the figures.

The adhesive layer 160 can be made with a single layer, or multiple layers using an adhesion layer of Cr, Ti, Al, Ni, W, Pt Au, any combination thereof, or the like, for example. In one embodiment, the adhesive layer 160 is conductive and includes a first layer with higher adhesion and lower electrical conductivity, such as Cr, Ti, Al, Ni, W, etc., and a second layer with lower adhesion and higher electrical conductivity, such as Pt Au, etc. The formation methods include electrolytic plating, electroless plating, sputtering, CVD methods, PVD methods, and the like. In some embodiments, the adhesive layer 160 covers the lower surface S2 of the lower substrate 110 and extends to cover inner surfaces of the lower through holes 114. In some embodiments, the adhesive layer 160 is conductive and covers a lower surface of the lower substrate assembly 110 and inner surfaces of the lower through holes 114 in a conformal manner. As such, the adhesive layer 160 can be in contact with the ground probes 144 and grounding when the ground probes 144 is in the lower through holes 114, so as to improve power coupling integrity and reduce coupling resistance of the circuit layer formed over the adhesive layer 160 subsequently.

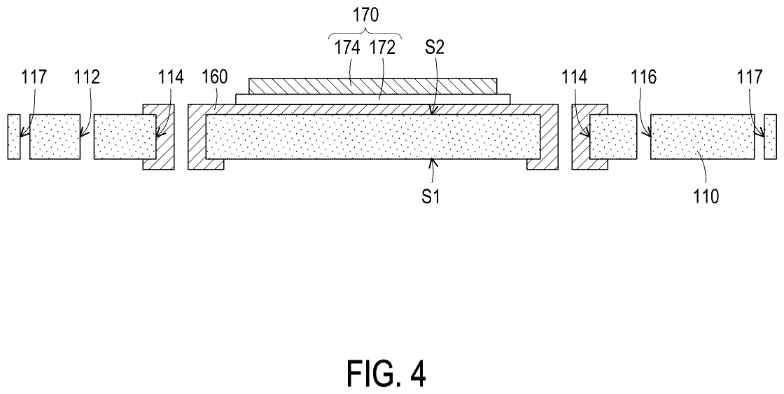

Then, referring to FIG. 4, the interconnect structure 170 is formed on the adhesive layer 160. The dielectric layer 172 of the interconnect structure 170 is deposited over the adhesive layer 160 on the lower substrate assembly 110. In some embodiments, the interconnect structure 170 includes the dielectric layer 172 and the circuit layer 174 disposed over the dielectric layer 172. In the present embodiment, the dielectric constant of the dielectric layer 172 is lower than the dielectric constant of the lower substrate 110 (e.g., ceramic materials or the like). For example, the dielectric layer 172 can be typically formed with dielectric materials having low dielectric constant (low-k) or extremely low dielectric constant in an effort to reduce parasitic capacitance of the circuit layer 174 formed thereon, thus increasing signal speed and enhance signal integrity. In one embodiment, the dielectric layer 172 may have a dielectric constant less than 8, and is formed with a porous organic dielectric material. As an example, the dielectric layer 172 includes diamond-like carbon (DLC), pure silica zeolite, phosphosilicate glass (PSG), borophosphosilicate glass (BPSG), fluorinated silicate glass (FSG), SiOxCy, Spin-On-Glass, Spin-On-Polymers, silicon carbon material, compounds thereof, composites thereof, combinations thereof, or the like, by any suitable method known in the art, such as spinning, chemical vapor deposition (CVD), and plasma-enhanced CVD (PECVD). It should also be noted that the dielectric layer 172 may include a plurality of dielectric layers.

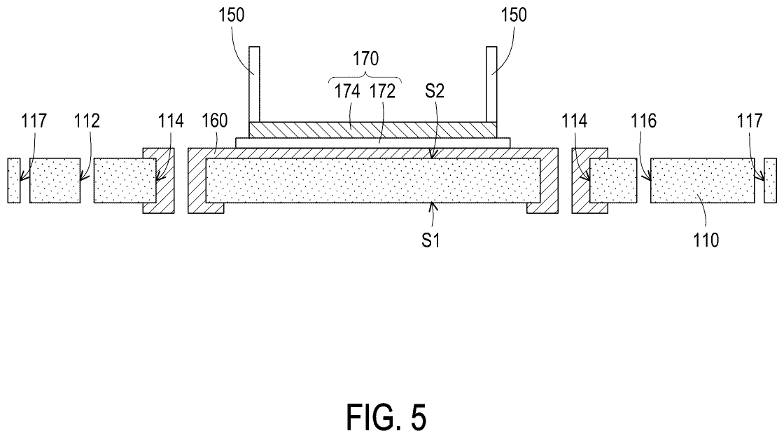

Then, referring to FIG. 5, in some embodiments, a plurality of second probes 150 are provided on the interconnect structure 170. In some embodiments, the second probes 150 are loopback probes, which are configured to be electrically connected to one another through the circuit layer 174 of the interconnect structure 170. In one embodiment, the second probes 150 may be deposited on the circuit layer 174 by three-dimensional (3D) printing process, or the like. By electrically connecting the second probes 150 through the interconnect structure 170 disposed on the lower surface S2 of the lower substrate 110, the electrical path of the signal from the DUT to the circuit layer 174 (loopback circuit) can be shorten, so as to increase the frequency performance of the probe head 100. For example, the length of the second probes 150 is substantially equal to or shorter than about 2.5 mm, and substantially equal to or longer than about 0.1 mm. The term “about” or “substantially” can be used to include any numerical value that can vary without changing the basic function of that value. When used with a range, “about” or “substantially” also discloses the range defined by the absolute values of the two endpoints, e.g., “about 2 to about 4” also discloses the range “from 2 to 4.” The term “about” or “substantially” may refer to plus or minus 10% of the indicated number.

Referring to FIG. 6, the resulting structure of the lower substrate 110 shown in FIG. 5 is then flipped over, and the spacer 130 is disposed on the lower substrate 110. For example, the lower substrate 110 can be fixed to the spacer 130 using screws or other suitable fixing elements 180. The upper surface S1 of the lower substrate 110 faces the spacer 130, and the lower surface S2 of the lower substrate 110 is opposite to the spacer 130. In some embodiments, the spacer 230 is made of metal, such as aluminum or other suitable materials.

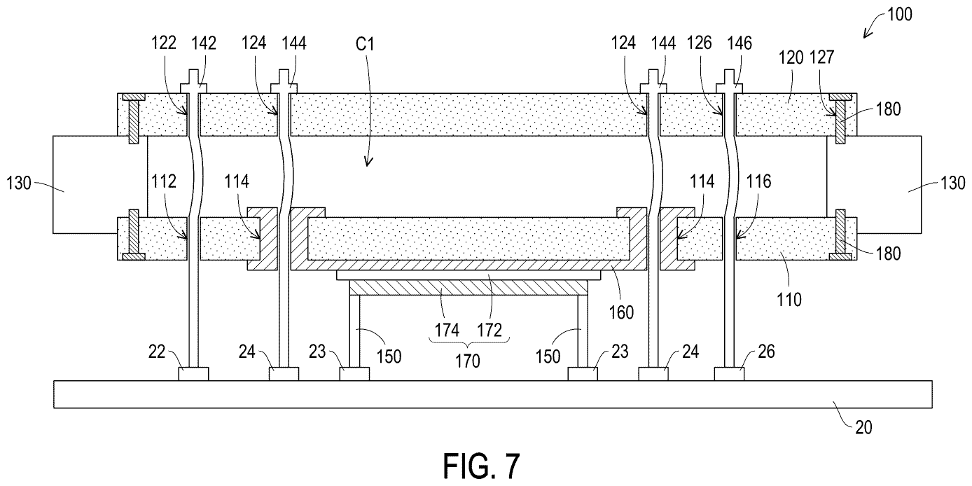

With now reference to FIG. 7, the upper substrate 120 is provided and mounted over the lower substrate 110 through the spacer 130. The upper substrate 120 includes a plurality of upper through holes 122, 124, 126. The first probes 142, 144, 146 are provided and extend through the lower through holes 112, 114, 116 and the upper through holes 122, 124, 126 respectively. The testing terminals (lower ends) of the first probes 142, 144, 146 are protruded from the lower through holes 112, 114, 116 of the lower substrate 110. The upper substrate 120 can be made of ceramic material or other suitable materials. The upper substrate 120 includes the upper through holes 122, 124, 126 that the first probes 142, 144, 146 can pass through, and a plurality of assembling holes 127 that fixing elements 180 can screw in. For example, the upper substrate 120 includes one I/O through hole 122, two ground through holes 124, and one power through hole 126 for receiving the corresponding I/O probe 142, ground probes 144, and power probe 146 therein, but the claimed scope is not limited in this respect.

In some embodiments, the upper substrate 120 can be fixed to the spacer 130 using screws or other suitable fixing elements 180. Alternatively, the upper substrate 120, the spacer 130, and the lower substrate assembly 110 can be fixed together using one set of fixing elements 180. The lower substrate assembly 110, upper substrate 120, and the spacer 130 together form a cavity C1 to accommodate the first probes 142, 144, 146. Hence, the connecting terminals (upper ends) of the first probes 142, 144, 146 respectively protrude from the upper through holes 122, 124,126. At this point, the manufacturing of the probe head 100 is substantially done.

Then, referring to FIG. 8 after the probe head 200 of FIG. 7 is assembled, the probe head 100 can be further assembled to the jig 400 of FIG. 8 to be connected to a circuit board 200 through a space transformer 300 and form a probe card assembly 10. In some embodiments, the probe card assembly 10 includes a circuit board 200, a space transformer 300, a jig 400, and the probe head 100 described above. The jig 400 may be a mounting ring mounted on the circuit board 200 through fixing elements 180, and the probe head 100 is disposed on the circuit board 200 through the jig 400. In detail, the spacer 130 is mounted on the jig 400 through the fixing elements 180 for connecting the probe head 100 to the circuit board 200. The probe head 100 includes the first probes 142, 144, 146 and the second probes 150, which may be of any suitable type and configuration such as needles or pins provided a suitable pitch spacing may be obtained to support 50 micron or less testing pad pitches in the embodiment. In the present embodiment, the first probes 142, 144, 146 each have a lower end configured and arranged for mating with a corresponding testing pad 22, 24, 26 on a DUT 20 to be tested, and the second probes 150 each have a lower end configured and arranged for mating with a corresponding testing pad 23.

The space transformer 300 is disposed over the circuit board 200 and may be a multi-layered organic (MLO) or multi-layered ceramic (MLC) interconnect substrate in some embodiments. The space transformer 300 may include a lower surface 320 with a fine pitch C4 contact test pad array for engaging and mating with contact ends (upper ends) of probe head 100, and an upper surface 330 with a ball grid array (BGA) for mating with corresponding contacts on the circuit board 200. A pitch of the contacts (BGA array) on the upper surface 330 is greater than a pitch of the contacts (C4 contact test pad array) on the lower surface 320 of the space transformer 300. In some embodiments, the probe card assembly 10 may further be mounted in an automated test equipment (ATE) and serve as an interface between the DUTs and the probe head 100 of the ATE.

FIG. 9 illustrates a partial bottom view of a lower substrate assembly of a probe head according to some embodiments of the present disclosure. Referring to FIG. 8 and FIG. 9, the adhesive layer 160, that is conductive, is grounding by in contact with the ground probe 144, so that the circuit layer 174 formed on the adhesive layer 160 can be closer to the ground to improve power coupling integrity and reduce coupling resistance of the circuit layer 174. Furthermore, the adhesive layer 160 is comprised of conductive metal to shield the DUT 20 from the circuit board 200 of the probe card assembly 10 to avoid inducing charges on the DUT 20. In some embodiments, the adhesive layer 160 can be formed over the surface where the interconnect structure 170 is formed. In the present embodiment, the adhesive layer 160 is formed over the lower surface of the lower substrate assembly 110. The I/O probes 142 and the power probes 146 can be insulated from the adhesive layer 160 by a variety of means. For example, the adhesive layer 160 includes at least one opening OP1 to leave out (expose) a surrounding region around the lower through hole 112 where the I/O probes 142 extending through, and at least one opening OP2 to leave out (expose) a surrounding region around the lower through hole 116 where the power probes 142 extending through, so that the I/O probes 142, the power probes 142, the ground probes 144, and the loopback probes 150 would not be shorting out.

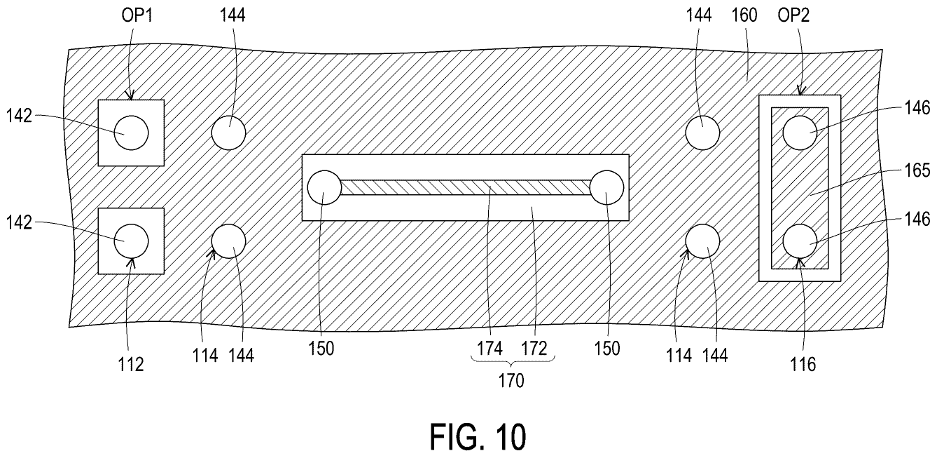

FIG. 10 illustrates a partial bottom view of a lower substrate assembly of a probe head according to other embodiments of the present disclosure. It is noted that the lower substrate assembly shown in FIG. 10 contains many features same as or similar to the lower substrate assembly disclosed in the previous embodiments. For purpose of clarity and simplicity, detail description of same or similar features may be omitted, and the same or similar reference numbers denote the same or like components.

Referring to FIG. 10, in some embodiment, the adhesive layer 160 is formed over the surface where the interconnect structure 170 is formed to improve power coupling integrity and reduce coupling resistance of the circuit layer 174, and to further shield the DUT 20 from the circuit board 200 to avoid inducing charges on the DUT 20. The I/O probes 142 and the power probes 146 can be insulated from the adhesive layer 160 by a variety of means. For example, the adhesive layer 160 includes a plurality of openings OP1 to expose a surrounding region around each of the lower through holes 112 where each of the I/O probes 142 extending through, and an opening OP2 to expose a surrounding region around the lower through holes 116 where the power probes 142 extending through. In the present embodiment, a conductive layer 165 is disposed in the opening OP2 and insulated from the adhesive layer 160. The conductive layer 165 electrically connects the power probes 142 disposed within the opening OP2, so that electric current can be evenly distributed to all the power probes 142 within the opening OP2. It is noted that the configurations and numbers of the probes 142, 144, 146, 150 shown in the figures are merely for illustration purpose, and the disclosure is not limited thereto.

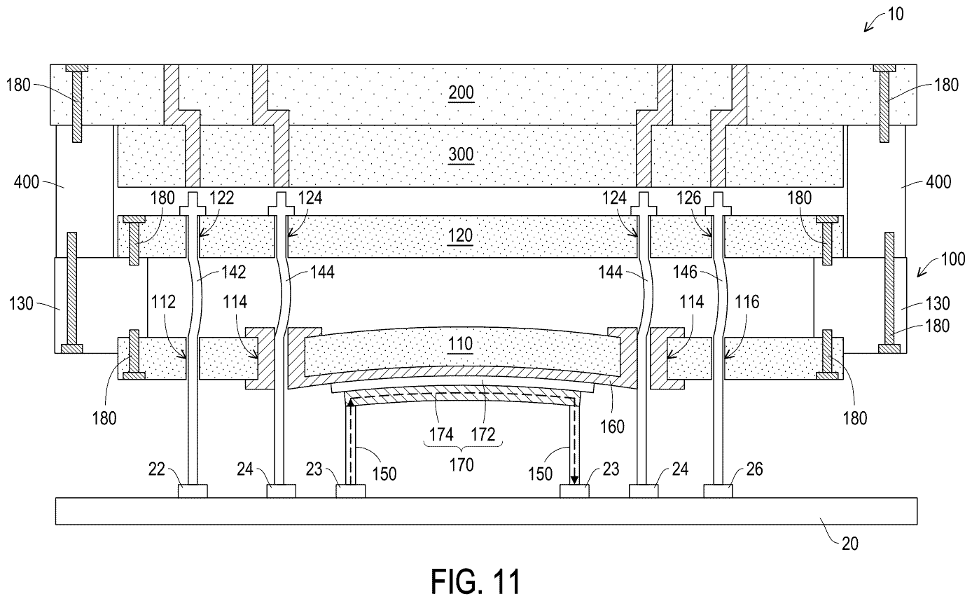

FIG. 11 illustrates a cross sectional view of a probe card assembly during testing according to some embodiments of the present disclosure. Referring to FIG. 11, with such configuration, by electrically connecting the second probes 150 through the interconnect structure 170 formed on the lower substrate assembly 110, the transmission paths of the signal from the DUT 20 to the loopback circuit (i.e., the circuit layer 174) can be shorten, so as to increase the frequency performance of the probe head 100. During the test, transmit electrical signal starts from the DUT 20 and routes from the transmitter test pad 23 (on the left) of the DUT 20 to the circuit layer 174 through the second probes 150 (on the left), and then loopback to the receiver test pad 23 (on the right) of the DUT 20 through the second probes 150 (on the right). The connection is accomplished by forming the loopback circuit 174 on the lower substrate assembly 110 with a shortest possible electrical length, so as to increase the frequency performance of the probe head 100.

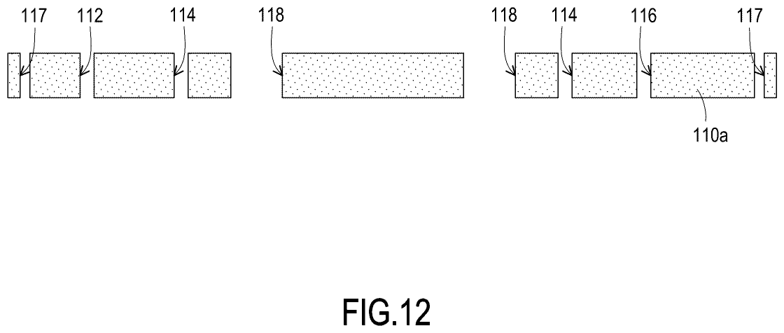

FIG. 12 to FIG. 17 illustrate cross sectional views of intermediate stages in the manufacturing of a probe card assembly according to some embodiments of the present disclosure. It is understood that additional operations can be provided before, during, and after the processes shown by FIG. 12 to FIG. 17, and some of the operations described below can be replaced or eliminated, for additional embodiments of the method. The order of the operations/processes may be interchangeable. Material, configuration, dimensions and/or processes the same as or similar to the foregoing embodiments described with FIG. 2 to FIG. 8 may be employed in the following embodiments, and detailed explanation thereof may be omitted.

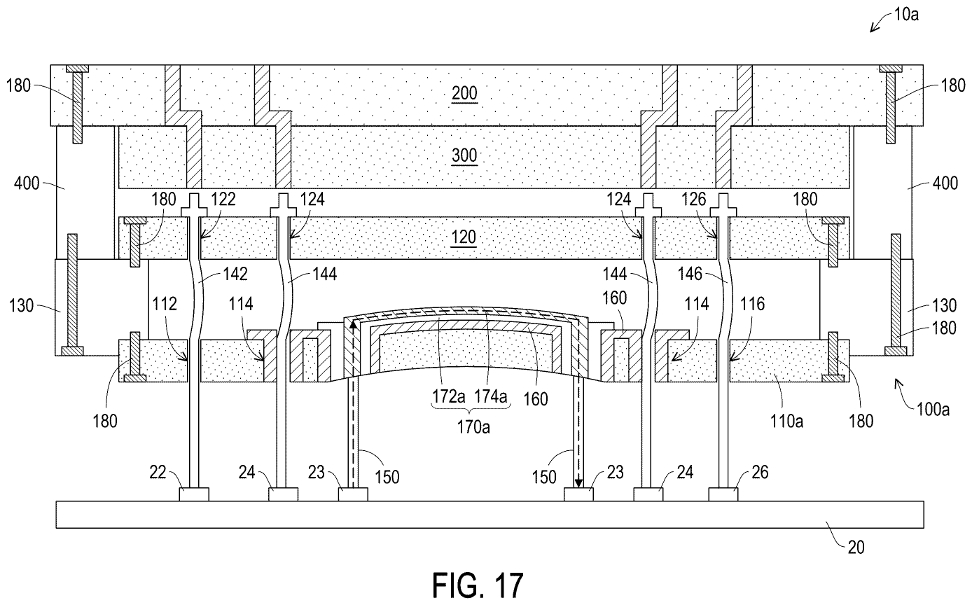

Referring firstly to FIG. 12 and FIG. 17, in some embodiments, a lower substrate assembly 110a is provided. The lower substrate assembly includes a lower substrate 110a having a plurality of lower through holes 112, 114, 116 that the first probes 142, 144, 146 of FIG. 17 can pass through, a plurality of interconnect through holes 118 that the interconnect structure 170a of FIG. 17 can fill in, and a plurality of assembling holes 117 that fixing elements 180 of FIG. 17 can screw in. For example, the first probes may include one I/O probe 142, two ground probes 144, one power probe 146. Correspondingly, the lower substrate 110a includes one I/O through hole 112, two ground through hole 114, and one power through hole 116 for receiving the corresponding I/O probe 142, ground probes 144, and power probe 146 respectively, but the numbers and configurations of the through holes can be modified according to the numbers and configurations of the probes, and are not limited in this respect. The lower substrate 110a can be made of ceramic material or other suitable materials.

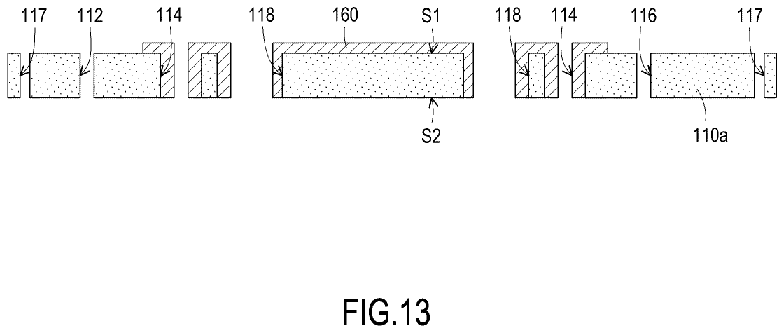

Then, referring to FIG. 13 and FIG. 17, the adhesive layer 160 is formed on a surface of the lower substrate 110. In the embodiment, the adhesive layer 160 is formed on an upper surface S1 of the lower substrate 110a and extended to cover inner surfaces of the interconnect through holes 118. It is noted that the upper surface S1 of the lower substrate 110a faces away from the DUT 20 during operation of electrical test. The adhesive layer 160 can be made with a single layer, or multiple layers using an adhesion layer of Cr, Ti, Al, Ni, W, Pt Au, any combination thereof, or the like, for example. In one embodiment, the adhesive layer 160 is conductive and includes a first layer with higher adhesion and lower electrical conductivity, such as Cr, Ti, Al, Ni, W, etc., and a second layer with lower adhesion and higher electrical conductivity, such as Pt Au, etc. The formation methods include electrolytic plating, electroless plating, sputtering, CVD methods, PVD methods, and the like. In the present embodiments, the adhesive layer 160 further extends to cover the inner surfaces of the lower through holes 114.

In some embodiments, to improve power coupling integrity and reduce coupling resistance of the circuit layer formed thereon subsequently, the adhesive layer 160 may be grounding by further covering the inner surfaces of the lower through holes 114 so that the adhesive layer 160 can be in contact with the ground probes (e.g., the ground probes 144 shown in 17) and grounding when the ground probes is in the lower through holes 114.

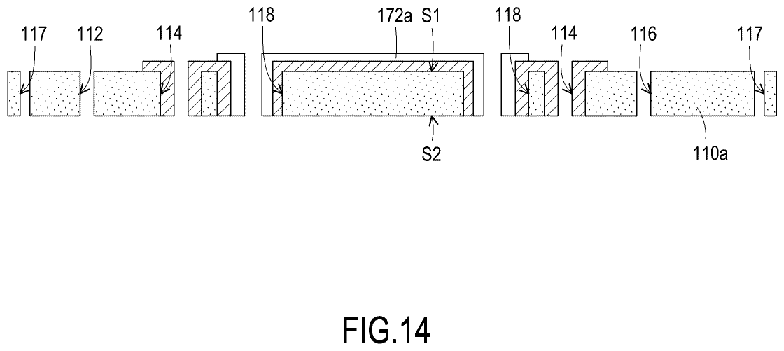

Then, referring to FIG. 14, a dielectric layer 172a is formed on the adhesive layer 160. Specifically, the dielectric layer 172a of the interconnect structure is deposited over the adhesive layer 160 for covering the inner surfaces of the interconnect through holes 118 and extending over the upper surface S1 of the lower substrate assembly 110a. In the present embodiment, the dielectric constant of the dielectric layer 172a is lower than the dielectric constant of the lower substrate 110a (e.g., ceramic materials or the like). For example, the dielectric layer 172a can be typically formed with dielectric materials having low dielectric constant (low-k) or extremely low dielectric constant in an effort to reduce parasitic capacitance of the circuit layer (e.g., the circuit layer 174a) formed thereon subsequently, thus increasing signal speed and enhance signal integrity of the circuit layer. In one embodiment, the dielectric layer 172a may have a dielectric constant less than 8, and is formed with a porous organic dielectric material. As an example, the dielectric layer 172a includes diamond-like carbon (DLC), pure silica zeolite, phosphosilicate glass (PSG), borophosphosilicate glass (BPSG), fluorinated silicate glass (FSG), SiOxCy, Spin-On-Glass, Spin-On-Polymers, silicon carbon material, compounds thereof, composites thereof, combinations thereof, or the like, by any suitable method known in the art, such as spinning, chemical vapor deposition (CVD), and plasma-enhanced CVD (PECVD). It should also be noted that the dielectric layer 172a may include a plurality of dielectric layers.

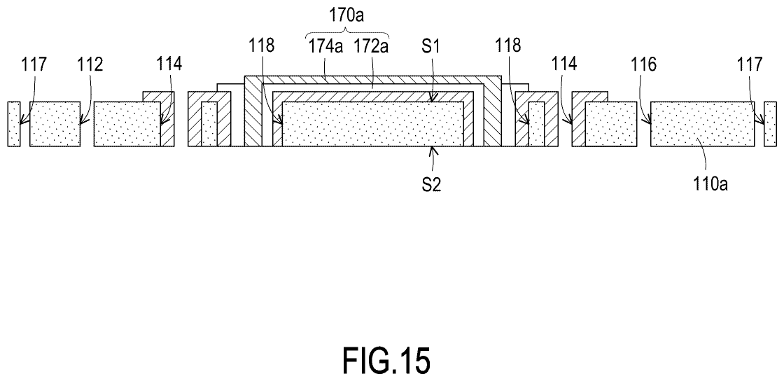

Then, referring to FIG. 15, a circuit layer 174a is formed over the dielectric layer 172a. In some embodiments, the circuit layer 174a fills the interconnect through holes 118 and extends over the upper surface S1 of the lower substrate assembly 110a. For example, the circuit layer 174a may include a low resistivity conductor material selected from the group of conductor materials including, but is not limited to, copper and copper-based alloy. In some embodiments, the circuit layer 174a may include various materials, such as tungsten, aluminum, gold, silver, titanium, or the like. The formation methods may include sputtering, printing, electroplating, electroless plating, and/or chemical vapor deposition (CVD) methods. The disclosure is not limited thereto. The dielectric layer 172a and the circuit layer 174a form an interconnect structure 170a, and the interconnect structure 170a fills the interconnect through holes 118 to function as through vias for electrically conducting the circuit layer 174a on the upper surface S1 to the lower surface S2 of the lower substrate 110a.

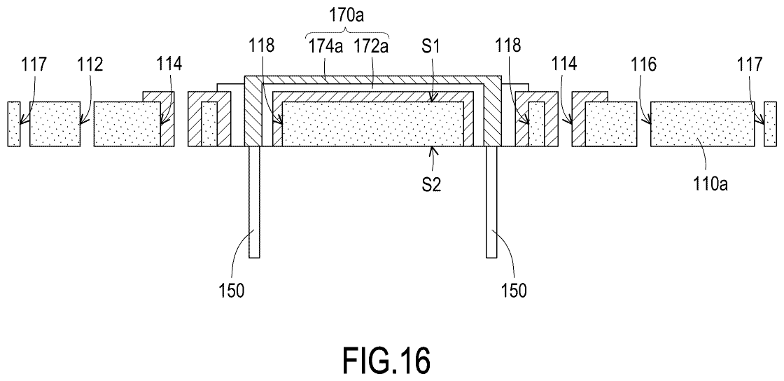

Then, referring to FIG. 16, in some embodiments, a plurality of second probes 150 are provided on the interconnect structure 170a. In some embodiments, the second probes 150 are loopback probes, which are configured to be electrically connected to one another through the circuit layer 174a of the interconnect structure 170a. In this embodiment, the second probes 150 is formed on the lower surface S2 of the lower substrate 110a and electrically connected to the circuit layer 174a. In one embodiment, the second probes 150 may be deposited on the circuit layer 174a by three-dimensional (3D) printing process, or the like. By electrically connecting the second probes 150 through the interconnect structure 170a on the lower substrate 110a, the electrical path of the signal from the DUT to the circuit layer 174a (loopback circuit) can be shorten, so as to increase the frequency performance of the probe head. For example, the length of the second probes 150 is substantially equal to or shorter than about 2.5 mm, and substantially equal to or longer than about 0.1 mm.

Then, the steps shown in FIG. 6 to FIG. 8 may be repeated herein to finish the assembling of the probe head 100a and the probe card assembly 10a as shown in FIG. 17. With such configuration, by electrically connecting the second probes 150 through the interconnect structure 170a formed on the lower substrate assembly 110a, the transmission paths of the signal from the DUT 20 to the loopback circuit (i.e., the circuit layer 174a) can be shorten, so as to increase the frequency performance of the probe head 100a. During the test, transmit electrical signal starts from the DUT 20 and routes from the transmitter test pad 23 (on the left) of the DUT 20 to the circuit layer 174a through the second probes 150 (on the left), and then loopback to the receiver test pad 23 (on the right) of the DUT 20 through the second probes 150 (on the right). The connection is accomplished by forming the loopback circuit 174a on the lower substrate assembly 110a with a shortest possible electrical length, so as to increase the frequency performance of the probe head 100a.

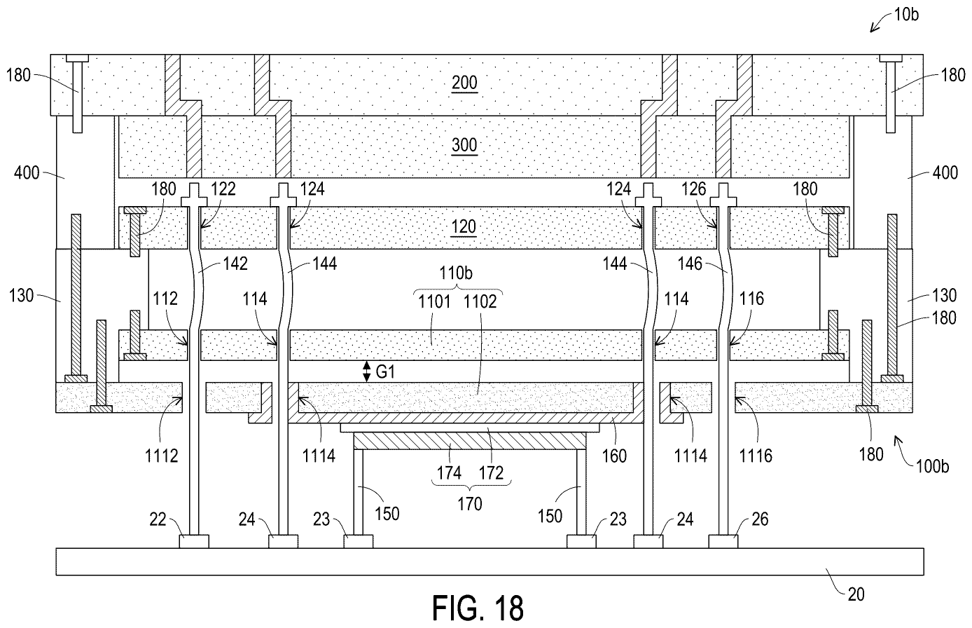

FIG. 18 illustrates a cross sectional view of a probe card assembly according to some embodiments of the present disclosure. It is noted that the probe card assembly shown in FIG. 18 contains many features same as or similar to the probe card assembly disclosed in the previous embodiments. For purpose of clarity and simplicity, detail description of same or similar features may be omitted, and the same or similar reference numbers denote the same or like components.

Referring to FIG. 18, in the present embodiment, the lower substrate assembly 110b includes a lower substrate 1101 and an auxiliary substrate 1102 disposed under the lower substrate 1101. The lower substrate 1101 includes the lower through holes 112, 114, 116 and the auxiliary substrate 1102 includes a plurality of auxiliary through holes 1112, 1114, 1116 corresponding to the lower through holes 112, 114, 116 respectively, so the first probes 142, 144, 146 extend through the lower through holes 112, 114, 116 and the auxiliary through holes 1112, 1114, 1116 respectively. In the present embodiment, the auxiliary substrate 1102 is mounted on a bottom surface of the spacer 130 through fixing elements 180 and spaced apart from the lower substrate 1101. That is, the spacer 130 is connected between the lower substrate 1101 and the auxiliary substrate 110 for maintaining a gap G1 between the lower substrate 1101 and the auxiliary substrate 110. In one embodiment, the gap G1 is substantially equal to or smaller than about 2 mm and substantially equal to or greater than about 0.1 mm. In some embodiments, the interconnect structure 170 is bonded to the lower surface of the auxiliary substrate 1102 through the adhesive layer 160.

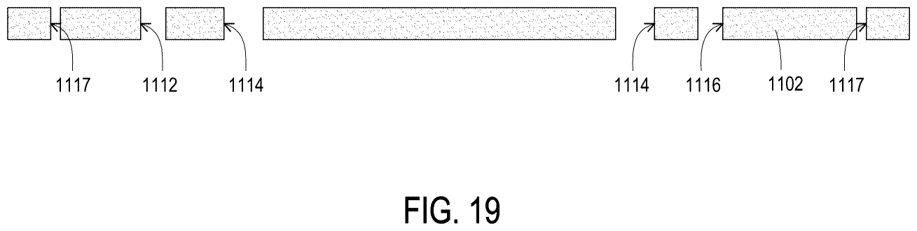

FIG. 19 to FIG. 23 illustrate cross sectional views of intermediate stages in the manufacturing of a probe card assembly according to some embodiments of the present disclosure. The manufacturing process of the probe card assembly shown in FIG. 18 is illustrated herein. It is understood that additional operations can be provided before, during, and after the processes shown by FIG. 19 to FIG. 23, and some of the operations described below can be replaced or eliminated, for additional embodiments of the method. The order of the operations/processes may be interchangeable. Material, configuration, dimensions and/or processes the same as or similar to the foregoing embodiments described with FIG. 19 to FIG. 23 may be employed in the following embodiments, and detailed explanation thereof may be omitted.

Referring to FIG. 18 and FIG. 19, in some embodiments, the auxiliary substrate 1102 is provided. The auxiliary substrate 1102 includes a plurality of auxiliary through holes 1112, 1114, 1116 that the first probes 142, 144, 146 of FIG. 18 can pass through, and a plurality of assembling holes 1117 that fixing elements 180 of FIG. 18 can screw in. For example, the first probes may include one I/O probe 142, two ground probes 144, and one power probe 146. Correspondingly, the auxiliary substrate 1102 includes the auxiliary through holes 1112, 1114, 1116 for receiving the corresponding I/O probe 142, ground probes 144, and power probe 146 therein, but the claimed scope is not limited in this respect. The auxiliary substrate 1102 can be made of any dielectric material that has a flexural strength substantially equal to or greater than about 50 Mpa. In some embodiment, the material of the auxiliary substrate 1102 may be the same or similar to the material of the lower substrate 1101.

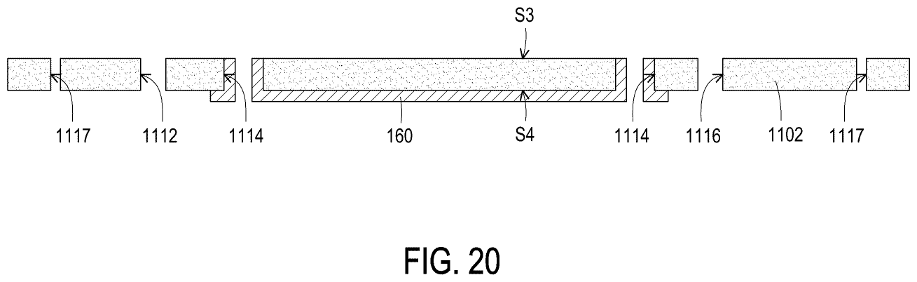

Referring to FIG. 18 and FIG. 20, in some embodiments, the adhesive layer 160 is formed on a surface of the auxiliary substrate 1102. In the embodiment, the adhesive layer 160 is formed on a lower surface S4 of the auxiliary substrate 1102, which would face the DUT 20 during electrical test. The adhesive layer 160 can be made with a single layer, or multiple layers using an adhesion layer of Cr, Ti, Al, Ni, W, Pt Au, any combination thereof, or the like, for example. In one embodiment, the adhesive layer 160 is conductive and includes a first layer with higher adhesion and lower electrical conductivity, such as Cr, Ti, Al, Ni, W, etc., and a second layer with lower adhesion and higher electrical conductivity, such as Pt Au, etc. The formation methods include electrolytic plating, electroless plating, sputtering, CVD methods, PVD methods, and the like. In some embodiments, the adhesive layer 160 covers the lower surface S4 of the auxiliary substrate 1102 and extends to cover inner surfaces of the auxiliary through holes 1114. In some embodiments, the adhesive layer 160 may further cover the inner surfaces of the auxiliary through holes 1114 in a conformal manner. As such, the adhesive layer 160 can be in contact with the ground probes 144 and grounding when the ground probes 144 is in the auxiliary through holes 1114, so as to improve power coupling integrity and reduce coupling resistance of the circuit layer that is formed over the adhesive layer 160 subsequently.

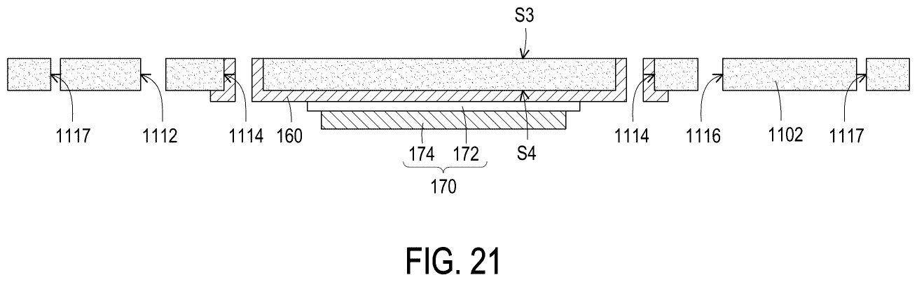

Referring to FIG. 21, the interconnect structure 170 is formed on the adhesive layer 160. The dielectric layer 172 of the interconnect structure 170 is deposited over the adhesive layer 160 on the auxiliary substrate 1102. In some embodiments, the interconnect structure 170 includes the dielectric layer 172 and the circuit layer 174 disposed over the dielectric layer 172. In the present embodiment, the dielectric constant of the dielectric layer 172 is lower than the dielectric constant of the auxiliary substrate 1102. For example, the dielectric layer 172 can be typically formed with dielectric materials having low dielectric constant (low-k) or extremely low dielectric constant in an effort to reduce parasitic capacitance of the circuit layer 174 formed thereon, thus increasing signal speed and enhance signal integrity. In one embodiment, the dielectric layer 172 may have a dielectric constant less than 8, and is formed with a porous organic dielectric material. As an example, the dielectric layer 172 includes diamond-like carbon (DLC), pure silica zeolite, phosphosilicate glass (PSG), borophosphosilicate glass (BPSG), fluorinated silicate glass (FSG), SiOxCy, Spin-On-Glass, Spin-On-Polymers, silicon carbon material, compounds thereof, composites thereof, combinations thereof, or the like, by any suitable method known in the art, such as spinning, chemical vapor deposition (CVD), and plasma-enhanced CVD (PECVD). It should also be noted that the dielectric layer 172 may include a plurality of dielectric layers.

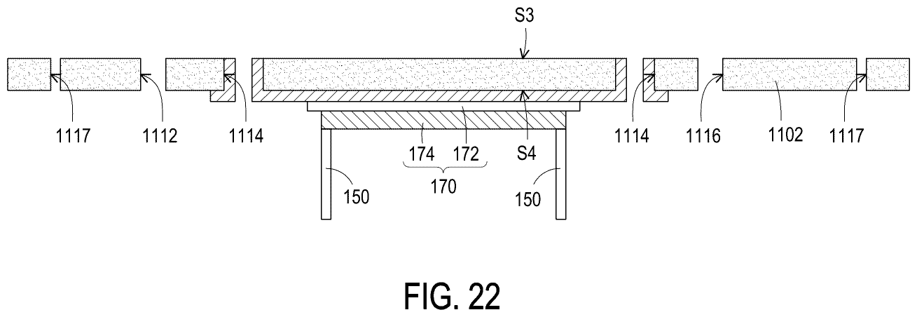

Then, referring to FIG. 22, in some embodiments, a plurality of second probes 150 are provided on the interconnect structure 170. In some embodiments, the second probes 150 are loopback probes, which are configured to be electrically connected to one another through the circuit layer 174 of the interconnect structure 170. In one embodiment, the second probes 150 may be deposited on the circuit layer 174 by three-dimensional (3D) printing process, or the like. By electrically connecting the second probes 150 through the interconnect structure 170 disposed on the lower surface S4 of the auxiliary substrate 1102, the electrical path of the signal from the DUT to the circuit layer 174 (loopback circuit) can be shorten, so as to increase the frequency performance of the probe head. For example, the length of the second probes 150 is substantially equal to or shorter than about 2.5 mm, and substantially equal to or longer than about 0.1 mm.

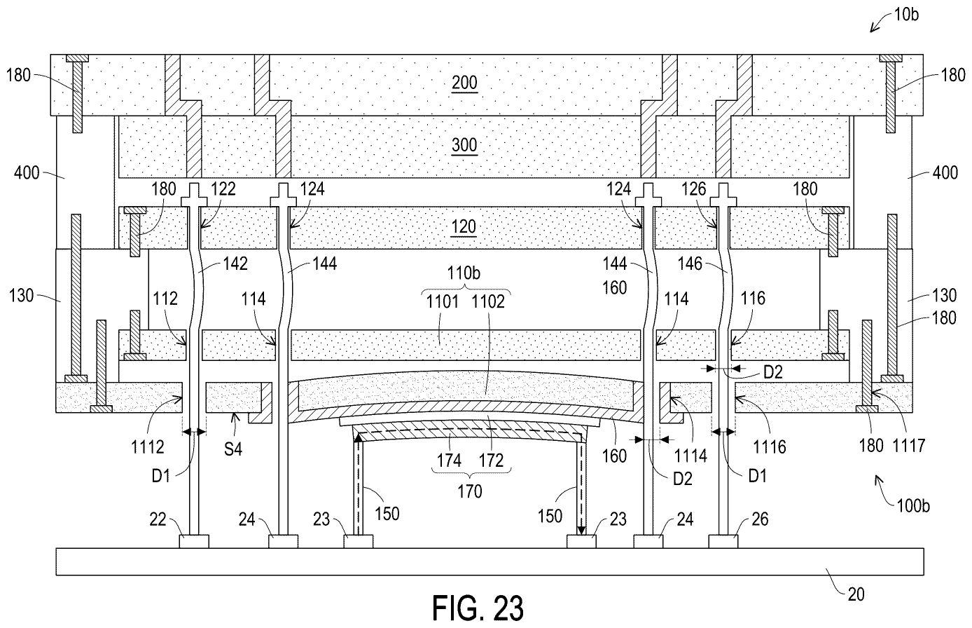

Then, the steps shown in FIG. 6 to FIG. 8 may be repeated herein to finish the assembling of the probe head 100b and the probe card assembly 10b as shown in FIG. 23. With such configuration, by electrically connecting the second probes 150 through the interconnect structure 170 formed on the auxiliary substrate 1102 disposed under the lower substrate 1101, the transmission paths of the signal from the DUT 20 to the loopback circuit (i.e., the circuit layer 174) can be shorten, so as to increase the frequency performance of the probe head 100b. During the test, transmit electrical signal starts from the DUT 20 and routes from the transmitter test pad 23 (on the left) of the DUT 20 to the circuit layer 174 through the second probes 150 (on the left), and then loopback to the receiver test pad 23 (on the right) of the DUT 20 through the second probes 150 (on the right).

In addition, the diameters of the auxiliary through holes may be greater than the diameters of the lower through holes. As such, a technician can simply detach the auxiliary substrate 1102 from the spacer 130 when the second probes 150 need maintenance or replacement without having to detach the lower substrate 1101. Also, the auxiliary substrate 1102 can be easily assembled back to the spacer 130 since the diameters D1 of the auxiliary through holes 1112, 1116 are greater than the diameters D2 of the lower through holes 112, 116. In detail, the auxiliary through holes 1112, 1116 and the lower through holes 112, 116 are configured for the I/O probes 142 and the power probes 146 to protrude therefrom. Accordingly, with the configuration of the diameters D1 of the auxiliary through holes 1112, 1116 greater than the diameters D2 of the lower through holes 112, 114, 116, the I/O probes 142 and the power probes 146 can be easily aligned with and protruding out from the auxiliary through holes 1112, 1116 when the auxiliary substrate 1102 is assembled back to the spacer 130, so as to enhance the ease of maintenance or replacement. In one embodiment, the diameter D2 of the auxiliary through holes 1114, which are configured for the ground probes 144 to protrude therefrom, may be about the same as the diameter D2 of the lower through holes 112, 114, 116, so the adhesive layer 160 can be coupled to the ground probes 144 when the ground probes 144 is disposed in the auxiliary through holes 1114.

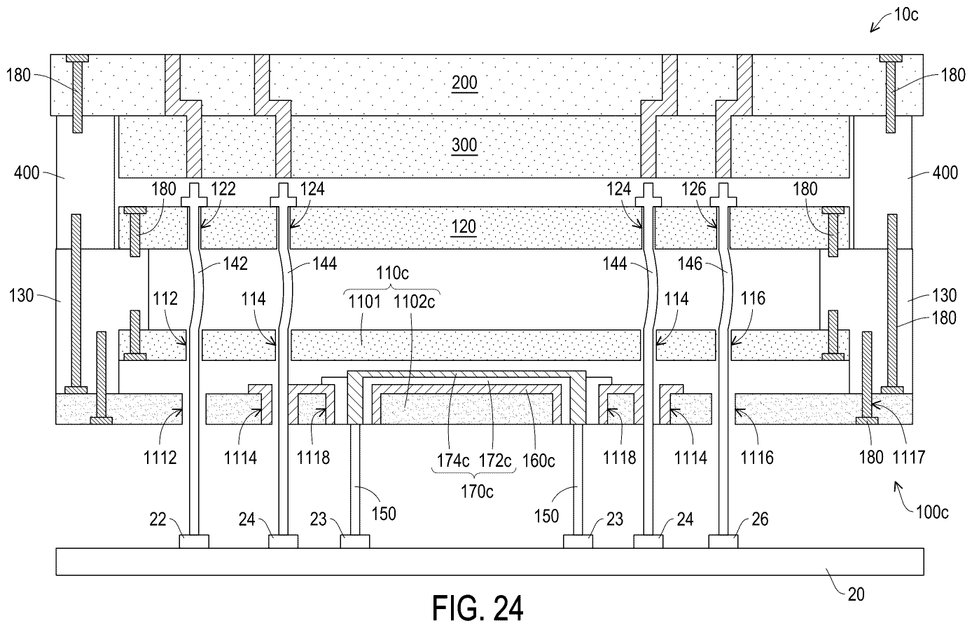

FIG. 24 illustrates a cross sectional view of a probe card assembly according to some embodiments of the present disclosure. It is noted that the probe card assembly shown in FIG. 24 contains many features same as or similar to the probe card assembly disclosed in the previous embodiments. For purpose of clarity and simplicity, detail description of same or similar features may be omitted, and the same or similar reference numbers denote the same or like components.

Referring to FIG. 24, in some embodiments, the auxiliary substrate 1102c further includes a plurality of interconnect through holes 1118. The lower substrate assembly 110c includes the lower substrate 1101 and the auxiliary substrate 1102c disposed under the lower substrate 1101 by mounting on the bottom surface of the spacer 130. The lower substrate 1101 includes the lower through holes 112, 114, 116 that the first probes 142, 144, 146 can pass through. Correspondingly, the auxiliary substrate 1102c includes the auxiliary through holes 1112, 1114, 1116 that the first probes 142, 144, 146 can pass through, and the interconnect through holes 1118 that interconnect structure 170c can fill in, and a plurality of assembling holes 1117 that fixing elements 180 can screw in. The numbers and configurations of the through holes can be modified according to the numbers and configurations of the probes, and are not limited in this respect.

The adhesive layer 160c is formed on an upper surface of the auxiliary substrate 1102c and extended to cover the inner surfaces of the interconnect through holes 1118. It is noted that the upper surface of the auxiliary substrate 1102c is the surface that faces away from the DUT 20 during operation of electrical test. The adhesive layer 160c can be made with a single layer, or multiple layers using an adhesion layer of Cr, Ti, Al, Ni, W, Pt Au, any combination thereof, or the like, for example. In one embodiment, the adhesive layer 160 is conductive and includes a first layer with higher adhesion and lower electrical conductivity, such as Cr, Ti, Al, Ni, W, etc., and a second layer with lower adhesion and higher electrical conductivity, such as Pt Au, etc. The formation methods include electrolytic plating, electroless plating, sputtering, CVD methods, PVD methods, and the like. In the present embodiments, the adhesive layer 160c further extends to cover the inner surfaces of the interconnect through holes 1118. In some embodiments, to improve power coupling integrity and reduce coupling resistance of the circuit layer formed thereon subsequently, the adhesive layer 160c may be grounding by further covering the inner surfaces of the auxiliary through holes 1114 so that the adhesive layer 160c can be in contact with the ground probes 144 and grounding when the ground probes 144 is in the auxiliary through holes 1114.

The interconnect structure 170c is formed over the adhesive layer 160c. Specifically, the dielectric layer 172c of the interconnect structure 170c is deposited on the adhesive layer 160c for covering the inner surfaces of the plurality of interconnect through holes 1118 and extending over the upper surface of the auxiliary substrate 1102c that faces the lower substrate 1101. In the present embodiment, the dielectric constant of the dielectric layer 172c is lower than the dielectric constant of the auxiliary substrate 1102c. For example, the dielectric layer 172c can be typically formed with dielectric materials having low dielectric constant (low-k) or extremely low dielectric constant in an effort to reduce parasitic capacitance of the circuit layer 174c, thus increasing signal speed and enhance signal integrity of the circuit layer 174c. In one embodiment, the dielectric layer 172c may have a dielectric constant less than 8, and is formed with a porous organic dielectric material. As an example, the dielectric layer 172c includes diamond-like carbon (DLC), pure silica zeolite, phosphosilicate glass (PSG), borophosphosilicate glass (BPSG), fluorinated silicate glass (FSG), SiOxCy, Spin-On-Glass, Spin-On-Polymers, silicon carbon material, compounds thereof, composites thereof, combinations thereof, or the like, by any suitable method known in the art, such as spinning, chemical vapor deposition (CVD), and plasma-enhanced CVD (PECVD). It should also be noted that the dielectric layer 172c may include a plurality of dielectric layers.

The circuit layer 174c of the interconnect structure 170c is formed over the dielectric layer 172c. In some embodiments, the circuit layer 174c fills the interconnect through holes 1118 and extends over the upper surface of the auxiliary substrate 1102c. For example, the circuit layer 174c may include a low resistivity conductor material selected from the group of conductor materials including, but is not limited to, copper and copper-based alloy. In some embodiments, the circuit layer 174c may include various materials, such as tungsten, aluminum, gold, silver, titanium, or the like. The formation methods may include sputtering, printing, electroplating, electroless plating, and/or chemical vapor deposition (CVD) methods. The disclosure is not limited thereto. The dielectric layer 172c and the circuit layer 174c form an interconnect structure 170c, and the interconnect structure 170c fills the interconnect through holes 1118 to function as through vias for electrically conducting the circuit layer 174c on the upper surface to the lower surface of the auxiliary substrate 1102c.

In some embodiments, the second probes 150 are provided on the interconnect structure 170c. In some embodiments, the second probes 150 are loopback probes, which are configured to be electrically connected to one another through the circuit layer 174c of the interconnect structure 170c. In this embodiment, the second probes 150 is formed on the lower surface of the interconnect through holes 1118 and electrically connected to the circuit layer 174c. In one embodiment, the second probes 150 may be deposited on the circuit layer 174c filling the interconnect through holes 1118 by three-dimensional (3D) printing process, or the like.

Then, the steps shown in FIG. 6 to FIG. 8 may be repeated herein to finish the assembling of the probe head 100c and the probe card assembly 10c as shown in FIG. 24. With such configuration, by electrically connecting the second probes 150 through the interconnect structure 170c formed on the auxiliary substrate 1102c disposed under the lower substrate 1101, the transmission paths of the signal from the DUT 20 to the loopback circuit (i.e., the circuit layer 174c) can be shorten, so as to increase the frequency performance of the probe head 100c. In addition, the diameters of the auxiliary through holes may be greater than the diameters of the lower through holes. As such, a technician can simply detach the auxiliary substrate 1102c from the spacer 130 when the second probes 150 need maintenance or replacement without having to detach the lower substrate 1101. Also, the auxiliary substrate 1102c can be easily assembled back to the spacer 130 since the diameters of the auxiliary through holes 1112, 1116 are greater than the diameters of the lower through holes 112, 116.

Based on the above discussions, it can be seen that the present disclosure offers various advantages. It is understood, however, that not all advantages are necessarily discussed herein, and other embodiments may offer different advantages, and that no particular advantage is required for all embodiments.

In accordance with some embodiments of the disclosure, a probe head for performing an electrical test on a device under test (DUT) includes an upper substrate including a plurality of upper through holes, a lower substrate assembly disposed under the upper substrate and including a plurality of lower through holes corresponding to the plurality of upper through holes respectively, a spacer connected between the upper substrate and the lower substrate assembly to maintain a gap between the upper substrate and the lower substrate assembly, a plurality of first probes extending through the plurality of upper through holes and the plurality of lower through holes respectively, an interconnect structure disposed on the lower substrate assembly and comprising a dielectric layer and a circuit layer, and a plurality of second probes disposed on the interconnect structure and electrically connected to one another through the circuit layer. In one embodiment, the lower substrate assembly further comprising an adhesive layer, and the interconnect structure is disposed over the adhesive layer on the lower substrate assembly. In one embodiment, the plurality of first probes comprises a ground probe for contacting a ground pad of the DUT, and the adhesive layer is conductive and covers an inner surface of one of the plurality of lower through holes where the ground probe protrudes therefrom. In one embodiment, the lower substrate assembly comprises a lower substrate comprising the plurality of lower through holes, and the interconnect structure is disposed on a lower surface of the lower substrate that faces the DUT. In one embodiment, a dielectric constant of the dielectric layer is lower than a dielectric constant of the lower substrate. In one embodiment, the lower substrate assembly comprises a lower substrate comprising the plurality of lower through holes and a plurality of interconnect through holes, the dielectric layer covers inner surfaces of the plurality of interconnect through holes and extends over an upper surface of the lower substrate that faces the upper substrate, and the circuit layer fills the plurality of interconnect through holes and extends over the upper surface of the lower substrate. In one embodiment, the lower substrate assembly further comprising an adhesive layer covering inner surfaces of the plurality of interconnect through holes and the upper surface of the lower substrate assembly, and the interconnect structure is disposed over the adhesive layer on the upper surface of the lower substrate assembly. In one embodiment, the plurality of first probes comprises a ground probe, and the adhesive layer is conductive and connected to the ground probe. In one embodiment, the lower substrate assembly further comprises a lower substrate comprising the plurality of lower through holes and an auxiliary substrate disposed under and spaced apart from the lower substrate, wherein the auxiliary substrate comprises a plurality of auxiliary through holes, and the plurality of first probes extending through the plurality of auxiliary through holes respectively. In one embodiment, the interconnect structure is bonded to a lower surface of the auxiliary substrate facing the DUT through an adhesive layer. In one embodiment, the auxiliary substrate further comprises a plurality of interconnect through holes, the dielectric layer covers inner surfaces of the plurality of interconnect through holes and extends over an upper surface of the auxiliary substrate that faces the lower substrate, and the circuit layer fills the plurality of interconnect through holes and extends over the upper surface of the lower substrate.

In accordance with some embodiments of the disclosure, a probe card assembly includes a circuit board, a space transformer, and a probe head. The space transformer is disposed over the circuit board. The probe head is disposed on the circuit board and includes an upper substrate, a lower substrate assembly disposed in parallel to the upper substrate, a spacer connected between the upper substrate and the lower substrate assembly, a plurality of first probes extending through the upper substrate and the lower substrate assembly, an interconnect structure disposed on the lower substrate assembly, and a plurality of second probes disposed on the interconnect structure and electrically connected to one another through the interconnect structure. In one embodiment, the probe card assembly further includes a jig mounted on the circuit board and configured to connect the probe head to the circuit board. In one embodiment, the spacer is mounted on the jig for connecting the probe head to the circuit board. In one embodiment, the lower substrate assembly further comprising an adhesive layer, and the interconnect structure is disposed on the lower substrate assembly through the adhesive layer, and the adhesive layer is conductive and coupled to a ground probe of the plurality of first probes.

In accordance with some embodiments of the disclosure, a method for manufacturing a probe head includes: providing a lower substrate assembly comprising a plurality of lower through holes; forming an adhesive layer on a surface of the lower substrate assembly; forming an interconnect structure on the adhesive layer; providing a plurality of loopback probes on the interconnect structure, wherein the plurality of loopback probes electrically connected to one another through the interconnect structure; mounting an upper substrate over the lower substrate assembly through a spacer, wherein the upper substrate having a plurality of upper through holes; and providing a plurality of probes extending through the plurality of upper through holes and the plurality of lower through holes respectively. In one embodiment, the plurality of lower through holes comprises a ground through hole, the plurality of probes comprises a ground probe extending through the ground through hole, the adhesive layer further covers an inner surface of the ground through hole and coupled to the ground probe. In one embodiment, the lower substrate assembly further comprises a plurality of interconnect through holes, and forming the interconnect structure further comprises: forming a dielectric layer covering inner surfaces of the plurality of interconnect through holes and extends over an upper surface of the lower substrate assembly; and forming a circuit layer on the dielectric layer, wherein the circuit layer fills the plurality of interconnect through holes and extends over the upper surface of the lower substrate assembly. In one embodiment, providing the lower substrate assembly further comprises: providing a lower substrate comprising the plurality of lower through holes; providing an auxiliary substrate comprising a plurality of auxiliary through holes, wherein the auxiliary substrate is disposed under the lower substrate, and the plurality of probes extend through the plurality of auxiliary through holes respectively. In one embodiment, the adhesive layer is formed on a lower surface of the auxiliary substrate where the interconnect structure is disposed.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A probe head for performing an electrical test on a device under test (DUT), comprising:
an upper substrate comprising a plurality of upper through holes;
a lower substrate assembly disposed under the upper substrate and comprising a plurality of lower through holes corresponding to the plurality of upper through holes respectively;
a spacer connected between the upper substrate and the lower substrate assembly to maintain a gap between the upper substrate and the lower substrate assembly;
a plurality of first probes extending through the plurality of upper through holes and the plurality of lower through holes respectively;
an interconnect structure disposed on the lower substrate assembly and comprising a dielectric layer and a circuit layer; and
a plurality of second probes disposed on the interconnect structure and electrically connected to one another through the circuit layer.

2. The probe head as claimed in claim 1, wherein the lower substrate assembly further comprising an adhesive layer, and the interconnect structure is disposed over the adhesive layer on the lower substrate assembly.

3. The probe head as claimed in claim 2, wherein the plurality of first probes comprises a ground probe for contacting a ground pad of the DUT, and the adhesive layer is conductive and covers an inner surface of one of the plurality of lower through holes where the ground probe protrudes therefrom.

4. The probe head as claimed in claim 1, wherein the lower substrate assembly comprises a lower substrate comprising the plurality of lower through holes, and the interconnect structure is disposed on a lower surface of the lower substrate that faces the DUT.

5. The probe head as claimed in claim 4, wherein a dielectric constant of the dielectric layer is lower than a dielectric constant of the lower substrate.

6. The probe head as claimed in claim 1, wherein the lower substrate assembly comprises a lower substrate comprising the plurality of lower through holes and a plurality of interconnect through holes, the dielectric layer covers inner surfaces of the plurality of interconnect through holes and extends over an upper surface of the lower substrate that faces the upper substrate, and the circuit layer fills the plurality of interconnect through holes and extends over the upper surface of the lower substrate.

7. The probe head as claimed in claim 6, wherein the lower substrate assembly further comprising an adhesive layer covering inner surfaces of the plurality of interconnect through holes and the upper surface of the lower substrate assembly, and the interconnect structure is disposed over the adhesive layer on the upper surface of the lower substrate assembly.

8. The probe head as claimed in claim 7, wherein the plurality of first probes comprises a ground probe, and the adhesive layer is conductive and connected to the ground probe.

9. The probe head as claimed in claim 1, wherein the lower substrate assembly further comprises a lower substrate comprising the plurality of lower through holes and an auxiliary substrate disposed under and spaced apart from the lower substrate, wherein the auxiliary substrate comprises a plurality of auxiliary through holes, and the plurality of first probes extending through the plurality of auxiliary through holes respectively.

10. The probe head as claimed in claim 9, wherein the interconnect structure is bonded to a lower surface of the auxiliary substrate facing the DUT through an adhesive layer.

11. The probe head as claimed in claim 9, wherein the auxiliary substrate further comprises a plurality of interconnect through holes, the dielectric layer covers inner surfaces of the plurality of interconnect through holes and extends over an upper surface of the auxiliary substrate that faces the lower substrate, and the circuit layer fills the plurality of interconnect through holes and extends over the upper surface of the lower substrate.

12. A probe card assembly comprising:
a circuit board;
a space transformer disposed over the circuit board; and
a probe head disposed on the circuit board and comprising:
an upper substrate;
a lower substrate assembly disposed in parallel to the upper substrate;
a spacer connected between the upper substrate and the lower substrate assembly;
a plurality of first probes extending through the upper substrate and the lower substrate assembly;
an interconnect structure disposed on the lower substrate assembly; and
a plurality of second probes disposed on the interconnect structure and electrically connected to one another through the interconnect structure.

13. The probe card assembly as claimed in claim 12, further comprising a jig mounted on the circuit board and configured to connect the probe head to the circuit board.

14. The probe card assembly as claimed in claim 13, wherein the spacer is mounted on the jig for connecting the probe head to the circuit board.

15. The probe card assembly as claimed in claim 12, wherein the lower substrate assembly further comprising an adhesive layer, and the interconnect structure is disposed on the lower substrate assembly through the adhesive layer, and the adhesive layer is conductive and coupled to a ground probe of the plurality of first probes.

16. A method for manufacturing a probe head, comprising:
providing a lower substrate assembly comprising a plurality of lower through holes;
forming an adhesive layer on a surface of the lower substrate assembly;
forming an interconnect structure on the adhesive layer;
providing a plurality of loopback probes on the interconnect structure, wherein the plurality of loopback probes electrically connected to one another through the interconnect structure;
mounting an upper substrate over the lower substrate assembly through a spacer, wherein the upper substrate having a plurality of upper through holes; and
providing a plurality of probes extending through the plurality of upper through holes and the plurality of lower through holes respectively.

17. The method for manufacturing the probe head as claimed in claim 16, wherein the plurality of lower through holes comprises a ground through hole, the plurality of probes comprises a ground probe extending through the ground through hole, the adhesive layer further covers an inner surface of the ground through hole and coupled to the ground probe.

18. The method for manufacturing the probe head as claimed in claim 16, wherein the lower substrate assembly further comprises a plurality of interconnect through holes, and forming the interconnect structure further comprises:
forming a dielectric layer covering inner surfaces of the plurality of interconnect through holes and extends over an upper surface of the lower substrate assembly; and
forming a circuit layer on the dielectric layer, wherein the circuit layer fills the plurality of interconnect through holes and extends over the upper surface of the lower substrate assembly.

19. The method for manufacturing the probe head as claimed in claim 16, wherein providing the lower substrate assembly further comprises:
providing a lower substrate comprising the plurality of lower through holes;
providing an auxiliary substrate comprising a plurality of auxiliary through holes, wherein the auxiliary substrate is disposed under the lower substrate, and the plurality of probes extend through the plurality of auxiliary through holes respectively.

20. The method for manufacturing the probe head as claimed in claim 19, wherein the adhesive layer is formed on a lower surface of the auxiliary substrate where the interconnect structure is disposed.
